(19) United States
(12) Patent Application Publication
(10) Pub. No.: US 2007/0046504 A1
(43) Pub. Date: Mar. 1, 2007

(54) Adaptive variable length codes for independent variables

(75) Inventors: Justin Ridge, Irving, TX (US); Marta Karczewicz, Irving, TX (US); Yiliang Bao, Irving, TX (US); Xianglin Wang, Santa Clara, CA (US)

Correspondence Address: FOLEY & LARDNER LLP, P.O. BOX 80278, SAN DIEGO, CA, 92138-0278, US

(73) Assignee: Nokia Corporation

(21) Appl. No.: 11/511,982

(22) Filed: Aug. 28, 2006

Related U.S. Application Data
(63) Continuation of application No. 11/490,384, filed on Jul. 20, 2006.
(60) Provisional application No. 60/701,264, filed on Jul. 21, 2005.
(60) Provisional application No. 60/723,060, filed on Oct. 3, 2005.

(51) Int. Cl. H03M 7/00

(52) U.S. Cl. 341/50

(57) ABSTRACT

A method for coding spatial and quality enhancement information in scalable video coding using variable length codes. Conventional systems have been capable of using variable length codes only with nonscalable video coding. In the present invention, the coded block pattern for each block of information, significance passes, and refinement passes can all be coded with different types of variable length codes. The present invention also provides for a variable length encoder/decoder that dynamically adapts to the actual symbol probability. The encoder/decoder of the present invention counts the number of times each symbol is coded. Based upon these counts, the encoder/decoder selects how many symbols to group when forming a code word. The encoder also uses these counts to select the specific codeword that should be used.

### FIELD OF THE INVENTION

The present invention relates generally to channel coding and data compression, as well as scalable video coding. More particularly, the present invention relates to coding in fine-granularity scalable video coding. The invention is primarily designed for use in video coding but can also be implemented for other types of data compression, such as speech/audio and still image compression.

### BACKGROUND OF THE INVENTION

Conventional video coding standards such as MPEG-1, H.261/263/264 encode video either at a given quality setting, which is commonly referred to as “fixed QP encoding,” or at a relatively constant bit rate via the use of a rate control mechanism. If the video needs to be transmitted or decoded at a different quality, the data must first be decoded and then re-encoded using the appropriate setting. In some scenarios, such as in low-delay real-time applications, this “transcoding” procedure may not be feasible.

Similarly, conventional video coding standards encode video at a specific spatial resolution. If the video needs to be transmitted or decoded at a lower resolution, then the data must first be decoded, spatially scaled, and then re-encoded. Again, such transcoding is not feasible in some scenarios.

Scalable video coding overcomes this problem by encoding a “base layer” with some minimal quality, and then encoding enhancement information that increases the quality up to a maximum level. In addition to selecting between the “base” and “maximum” qualities through inclusion or exclusion of the enhancement information in its entirety, the enhancement information may often be truncated at discrete points, permitting intermediate qualities between the “base” layer and “maximum” enhancement layer. For quality enhancement, the information may often be truncated at discrete (but closely-spaced) points, affording additional flexibility by permitting intermediate qualities between the “base” and “maximum” to be achieved. In cases where the discrete truncation points are closely-spaced, the scalability is referred to as being “fine-grained,” from which the term “fine grained scalability” (FGS) is derived.

The current scalable extension to H.264/AVC employs CABAC, a type of arithmetic coder, when decoding spatial and quality enhancement information. CABAC is an alternative entropy coding method to variable length codes (VLCs). Although CABAC generally has a coding efficiency benefit, it is understood that there are a number of disadvantages associated with it, such as increased decoder complexity. Furthermore, no VLC alternative is provided for the current scalable extension to H.264/AVC. The non-scalable H.264/AVC standard supports both CABAC and VLCs, recognizing that each has advantages and disadvantages, and allowing for the method most suitable to a specific application to be selected.

In addition, with scalable video coding, fine-grained scalability information may be coded into a bit stream using variable length codes or arithmetic coding. It is desirable to improve coding efficiency when using variable length codes instead of arithmetic coding. Previously, values were either coded as independent flags or were collected into fixed-length groups and encoded using a VLC that was not context adaptive.

Variable length codes are designed so that shorter codewords are assigned to symbols having higher probabilities of occurring, and longer codewords are assigned to symbols having lower probabilities of occurring. More particularly, a symbol v with a probability p(v)=2^{-k} will be assigned a codeword of length k bits.

When the probability distribution used in designing the variable length code table does not match the actual symbol probabilities in a specific bit stream, the compression efficiency of the variable length code degrades. There are generally two factors that contribute to such a “probability mismatch.” First, the actual symbol probability may not be known in advance, so the variable length code must be designed using some type of generalized “training data.” Techniques for overcoming this problem include transmitting the code table in the bit stream header or signaling which one out of several pre-designed variable length codes most accurately matches the source data. Second, although the symbol probabilities may be known in advance, they may not correspond to p(v)=2^{-k}, since k is restricted to integer values. This is a structural limitation and is often overcome by grouping several symbols and assigning one codeword to each possible grouping. For example, in the binary case, the two symbols 0 and 1 could be grouped in pairs, yielding the possible combinations 00, 01, 10, 11. Because k retains the same integer constraint, this effectively doubles the precision of the probability equation.

The “work-around” techniques described above are conventionally known but are often impractical. For example, if the probability distribution is subject to significant local variation (e.g., from one frame to another in video coding), the overhead associated with coding the optimal VLC table into the bit stream may be too large. In other cases, the number of symbols that may need to be combined in order to accurately represent the probability distribution may exceed the number of symbols to be decoded, or it may add unwanted complexity to the decoding path. Arithmetic coding can be used to help overcome these limitations described above. For example, an arithmetic coder such as CABAC self-adapts to the symbol probability so that no bit stream signaling is required, and such a coder is not subject to the finite set of symbol probabilities (i.e., k is not constrained to being an integer in the equation p(v)=2^{-k}) However, arithmetic coding has its own set of drawbacks. It is generally more complex than other systems discussed above, and the need to “read ahead” when decoding makes it difficult to truncate data and maintain a valid decoder state.

Therefore, it is desirable to have an entropy coding mechanism exhibiting the positive characteristics of both variable length codes (i.e., low complexity, instantaneously decodable/easily truncatable) and arithmetic coding (i.e., self-adapting and being better able to model symbol probability).

### SUMMARY OF THE INVENTION

The present invention provides for improved coding efficiency when using variable length codes (VLC). The present invention also provides a system with the ability to automatically adapt to changes in characteristics of the source data. Compared to existing VLC-based solutions, the present invention adapts to symbol probabilities dynamically, so that there is no need to specify the VLC table explicitly in the bit stream. The present invention also provides for coding efficiency gains when coding independent variables, compared to many existing VLC-based solutions that exploit correlation between symbols. Additionally, the internal state of a solution of the present invention is simpler than is the case with prior arithmetic coding solutions. Each codeword is decodable independent of future values, meaning that, for example, the bit stream may be truncated without the need to “re-write” a modified buffer to the bit stream.

The present invention provides methods for improving the coding efficiency for FGS layers when using variable length codes. When decoding the coded block pattern (CBP), the variable length coding to be used is dependent upon the number of ones and zeros in the corresponding base layer CBP, as well as on the probability of a block being coded. The probability of a block being coded is based upon previously observed CBPs. When decoding the coded block flags (CBFs), a single codeword is decoded to represent multiple CBFs. The variable length coding that is used depends upon the probability of previous CBF values being one. When decoding an end of block (EOB) flag, “illegal symbols” are used to indicate the number of coefficients in the block with magnitude greater than one and/or the maximum magnitude within the block. When decoding refinement bits, groups of one or more refinement bits are decoded from a single VLC codeword, where the VLC that is used is based upon previously-observed refinement values.

The present invention can be implemented directly in software using any common programming language, e.g. C/C++, or assembly language. The present invention can also be implemented in hardware and used in a wide variety of consumer devices.

The present invention also provides a method for decoding spatial and quality (FGS) enhancement information using variable length codes. The present invention provides a solution using VLCs in scalable video coding, which has not previously existed. Although the use of VLCs may entail a slight loss (in the range of about 10%) in computational efficiency, this loss is offset by improvements in coder complexity. In fact, the observed tradeoff for enhancement layers is quite similar to the tradeoff that has already been accepted for the non-scalable H.264/AVC standard.

These and other advantages and features of the invention, together with the organization and manner of operation thereof, will become apparent from the following detailed description when taken in conjunction with the accompanying drawings, wherein like elements have like numerals throughout the several drawings described below.

### BRIEF DESCRIPTION OF THE DRAWINGS

FIG. 1 is a plot comparing the number of bits required for each symbol to the probability of a block containing no values to be decoded for three different variable length codes;

FIG. 2 is a flow chart showing a general encoding/decoding process of the present invention;

FIG. 3 is a flow chart showing a first example process for updating the current variable length code in the flow chart of FIG. 2;

FIG. 4 is a flow chart showing a second example process for updating the current variable length code in the flow chart of FIG. 2, wherein an update is performed after every fourth codeword;

FIG. 5 is a flow chart showing a third example process for updating the current variable length code in the flow chart of FIG. 2, wherein an initial value for the variable length code is specified until the number of observed symbols exceeds eight;

FIG. 6 is a flow chart showing an encoding/decoding process of the present invention, wherein the system “bit flips” the symbol vectors after decoding if p(0)<p(1);

FIG. 7 is a flow chart showing an encoding/decoding process of the present invention, wherein buffer flushes are included in the encoding/decoding process;

FIG. 8 is a perspective view of an electronic device that can incorporate the principles of the present invention; and

FIG. 9 is a schematic representation of the circuitry of the electronic device of FIG. 8.

### DETAILED DESCRIPTION OF THE PREFERRED EMBODIMENTS

Generally, quality enhancement information can be divided into three categories: coded block pattern, significance pass, and refinement pass. For the coded block pattern, a “coded flag” is decoded for each macroblock (MB), or for a region of the macroblock, such as an 8×8 region “sub-MB.” The flag only needs to be decoded if the “coded flag” for the corresponding macroblock in all lower layers was zero, i.e. if the MB was not coded in the base layer or other lower layers. It should be understood that, although text and examples contained herein may specifically describe an decoding process, one skilled in the art would readily understand that the same concepts and principles also apply to the corresponding encoding process and vice versa.

For MBs (or sub-MBs) that are flagged as “coded,” the coded block pattern for each 4×4 block within the MB (or sub-MB) is then decoded. In each 8×8 region of a MB, there are four 4×4 blocks, for example. A binary number can be used to indicate which of the 4×4 blocks contain coefficients to be encoded. The number 0101 can indicate that the top-left 4×4 block has no coefficients to be decoded, the top-right 4×4 block was encoded, the bottom-left was not encoded, and the bottom-right was encoded. If the 4×4 block was already flagged as coded in the base layer, no CBP value is decoded. Therefore, unlike non-scalable H.264/AVC, the number of bits in the CBP may vary. Using the above example, if the bottom-right 4×4 block was already encoded in the base layer, the last bit of the CBP is unnecessary and the CBP becomes 010.

A VLC is used to decode the CBP. The specific VLC that is used depends upon the number of bits in the CBP. The VLC is therefore “context adaptive” (CAVLC), where the context (i.e. the VLC used) is provided by the CBP of the base layer. The context decision can also be affected by the CBP of spatially neighboring blocks in the base and/or enhancement layers. It is also possible for the context decision to be based at least in part upon the number of coded coefficients in neighboring blocks, or by the positions of coded coefficients in neighboring blocks in the enhancement layer.

The VLCs that may be used may be custom designed or may comprise “structured” VLCs such as Golomb codes. A Golomb code is variable-length code that is based on a simple model of the probability of values, where small values are more likely than large values.

Significance bits are decoded whenever a coefficient was zero in all lower layers, i.e. it has not been decoded up to the current layer. The significance bit indicates whether the coefficient is zero or nonzero. If the coefficient is nonzero, then the sign and magnitude follow.

In the present invention, the number of zeros (i.e. the run) is encoded before the next significant coefficient. For example, if the base layer contains values 1 0 1 0 0 1, and the enhancement layer contains values 1 0 2 0 1 1, then the first, third and sixth coefficients are disregarded for the purpose of decoding significance bits, as they were non-zero in the base layer. Thus the values to be decoded are 0 0 1. In this case, the “run” of zeros before the non-zero value is two. The term “scan position” is defined herein as the index of the coefficient where the run begins. In the above example, the first coefficient is ignored, so the first zero value decoded is at scan position two. The VLC used to decode the “run” is also context-adaptive and depends on the scan position, the number of coefficients coded in the base layer (three, in the above example), the index of the last coefficient coded in the base layer (six, in the above example), or a combination of the three. It should also be noted that the present invention can involve the VLC as not being structured (i.e., where an arbitrary VLC is selected), as well as the more narrow situation where “structured” VLCs, such as Golomb codes or start-step-stop codes are used.

In a particular embodiment of the present invention, a mapping of the context criteria to the optimal VLC is decoded from the bit stream. This could occur, for example, once per slice (in the slice header) or once per frame. It may specify that “for scan position #1 use a Golomb code with k=1”, “for scan position #2 use a Golomb code with k=1”, “for scan position #3 use a Golomb code with k=2”, etc. Determining which context criteria maps to which VLC may be accomplished by “pre-scanning” the data before encoding, or by utilizing statistics of previously encoded data (e.g. the previous frame). It should be noted that the bit stream to be decoded can be received from a remote device located within virtually any type of network. Additionally, the bit stream can be received from local hardware or software.

In yet another embodiment of the present invention, the mapping of context criteria to VLC is coded in an efficient manner. To achieve this, the possible VLCs are ordered in a regular fashion. For example, the possible VLC's could be ordered from “most peaked” probability distributions (high peak at the first symbol value) to the “least peaked”, or flatter distributions. The VLCs themselves are given indexes. For example, the first VLC may be a Golomb code with parameter k=1, the second VLC may be a Golomb code with parameter k=2, etc. By then forcing the VLC to be a monotonic (increasing or decreasing) function of the context selection criteria, there is an overall improvement in coding efficiency. This efficiency occurs even though there is a slight loss of optimality in VLC selection. Using the above example, the VLCs used for scan positions 1, 2 and 3 would be 1, 1 and 2 respectively, which can be written as 1 1 2. Sequences such as 1 2 1 are not permitted since they are not monotonic. Due to the monotonic nature of the function, only the starting VLC and the position of the step need to be decoded. For example, rather than explicitly decoding the values “1 1 2”, the starting VLC (“1”) can be decoded, followed by the number of those values before a step to the next level.

The embodiment described above can be extended to a situation where there are two or more context selection criteria. This can be accomplished by drawing the mapping function as a two (or ‘n’) dimensional table and enforcing monotonicity along each dimension. In another example, the VLC is selected based upon both the scan position as well as the position of the last nonzero base layer coefficient. In this case, the mapping for optimal VLCs may be, for example:
1 1 2
2 2 2
1 2 2

In this table, the first row corresponds to the case where the last nonzero base layer coefficient (LNZBC) was at position 1, the second row corresponds to the case where the LNZBC was at position 2, etc. It should be noted that each row monotonically increases, but the first column does not. By enforcing this constraint, the table can be rewritten as:
1 1 2
2 2 2
2 2 2

or alternatively as
1 1 2
1 2 2
1 2 2

In this situation, the run-level coding can be applied along each dimension. For example, the first row can be decoded as described above. The starting position can then be used from the first row when decoding each column. When implemented, this avoids coding of most values except for the upper-left corner of the matrix.

In still another embodiment of the present invention, an end-of-block (EOB) marker is used to indicate that there are no more coefficients that need to be decoded in the significance pass for a given block. The EOB is treated as another possible run length (with notional value −1) when decoding the significance bits.

For structured VLCs, the lowest-valued symbols should have the highest probability. In some cases, the EOB does indeed have the highest probability of all symbols, but this is not always the case. This can be overcome by decoding from the bit stream (e.g. slice header) values indicating the EOB symbol position in the VLC. This can be performed once or, to achieve further coding efficiency gains, can be performed once for some or all of the context selection criteria. For example, it can be decoded once for each scan position. The same monotonicity constraint and decoding method may be applied for decoding the EOB symbol position as described above for the VLC mapping. In still another embodiment, the EOB symbol may be designated as having very low probability for some context criteria. To improve coding efficiency, a distinct symbol may be decoded indicating the number of such “low probability” EOB symbols. Decoding of the remaining EOB symbols then follows as described previously.

The above text has focused on decoding the positions of significant coefficients, without considering the sign or magnitude of the terminating values. In general, most values have a magnitude of zero or one. Magnitudes of two to four are also possible.

One method of improving coding efficiency is to divide the significance bits into two passes. On the first pass, no magnitude is decoded. Instead, only position information and the sign flag is decoded. The magnitude of significant coefficients is assumed to be one. On a second pass, the positions of coefficients with higher magnitudes are encoded. For example, if one were to decode values 0 0 1 0 0-3 1 0, the values 0 0 1 0 0-1 1 0 would be initially decoded. In this situation, there are three significant coefficients with magnitude one. Then in a second pass, a “two” is decoded, indicating that the second of the unit-magnitude coefficients in reality has a larger magnitude (a magnitude of 3 in this case). After identifying the position of the larger-magnitude coefficient, the precise magnitude (e.g., 2, 3 or 4) is decoded. One fixed VLC may be used for this purpose. In another embodiment of the invention, this VLC itself may be context-adaptive and selected based upon criteria such as the scan position, number of unit magnitude values, dead zone size, enhancement layer number, other factors, and a combination of such factors. In another embodiment of the invention, the process is iterated so that coefficients with a magnitude of 2 are decoded on a second pass, coefficients with a magnitude of 3 are decoded on a third pass, and coefficients with a magnitude of 4 are decoded on a fourth pass. This iterative process obviates the need to decode magnitude information in each cycle.

Lastly, refinement bits are transmitted when the coefficient is non-zero in a lower layer. Refinement bits comprise magnitude and sign information. Refinement bits are grouped into fixed-size lots. In one particular embodiment of the invention, the refinement bits are grouped into lots of three, although other sizes may be used. For example, in three bit groupings, if the refinement bits are 0 0 0 1 1 0 1 0 0 1, then this would be grouped into [0 0 0] [1 1 0] [1 0 0] [1]. It should be noted that the last set may contain fewer than three values. The symbols corresponding to the binary values are then encoded using a VLC. In the example above, the symbols 0, 6, 4, and 1 are encoded.

The VLC used to encode the symbol is either decoded from the bit stream, is inferred from previously decoded data, or is based upon the FGS layer number. The possible VLCs are structured in decreasing order of probability of zero. For example, in a VLC reflecting a higher probability of zero, the shortest codeword is used to represent the value 000, the next-shortest codewords for the values 001, 010, 100, etc. The lowest probability of a zero symbol is the 50% case, when the symbol and the codeword are equivalent.

When the last symbol is encoded, only flags are used (and no VLC) since the loss of efficiency is marginal. It is also possible for the last codeword to either be padded, or for a different VLC (selected based on the VLC used for other values) to be used.

Sign bits are encoded in a manner similar to that described above. However, there tends to be only two cases for sign bits; the distribution tends to either be skewed towards zero for the first enhancement layer, or towards 50% ones and 50% zeros for subsequent enhancement layers. The VLC is therefore dependant on the enhancement layer number. In the 50/50 case, flags are encoded rather than the values being grouped.

With the present invention, the encoding of spatial enhancement information is generally similar to the regular, non-scalable encoding under H.264/AVC. However, additional and/or different VLCs can be used when encoding spatially upsampled information, and that the context that is used can be based on lower-layer information rather than the spatial neighbors.

In general, for a given VLC, the average number of bits required for each symbol is

$$R = {\sum }_{v ∈ X} p ( v ) L ( v ) ,$$

where p(v) is the probability of symbol v drawn from alphabet X, and L(v) is the length of the codeword assigned to symbol v. This equation can be extended to describe a VLC where a group (or ‘vector’) of symbols are encoded together as

$$R = \frac{1}{N} \sum p ( \overline{v} ) L ( \overline{v} ) .$$

In this equation, N is the number of symbols to be grouped, v̅={v₁, v₂, . . . , v_{N}}, i.e., a vector of symbols, and the sum is over all possible values of this vector. In a preferred embodiment of the invention, the alphabet X contains the symbols 0 and 1, with p(1)=1−p(0). Therefore, for a given VLC codeword table, the value R is a function of p(0).

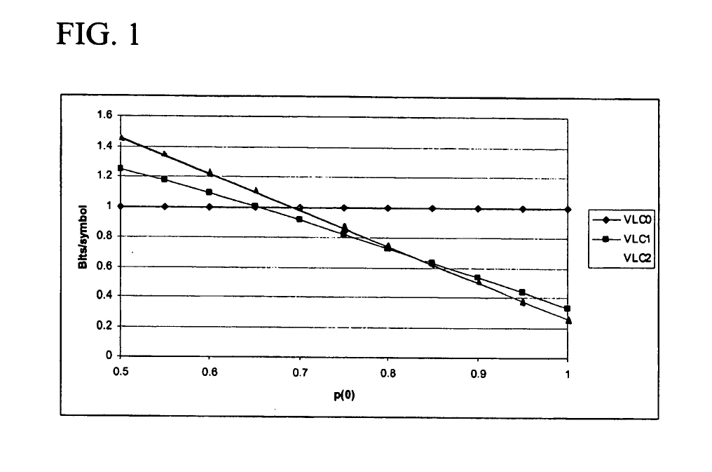

Tables 1(a)-1(c) show three example VLC codeword tables. In this situation, the codewords are selected so that symbol vectors containing more zeros have shorter codewords. The corresponding plot of R vs. p(0) for each codeword table is shown in FIG. 1

TABLE 1(a)

| Symbol, ν̅ | Codeword |
|---|---|
| 0 | 0 |
| 1 | 1 |

VLC0, N = 1

TABLE 1(b)

| Symbol, ν̅ | Codeword |
|---|---|
| 000 | 0 |
| 001 | 100 |
| 010 | 101 |
| 011 | 11100 |
| 100 | 110 |
| 101 | 11101 |
| 110 | 11110 |
| 111 | 11111 |

VLC1, N = 3

TABLE 1(c)

| Symbol, ν̅ | Codeword |
|---|---|
| 0000 | 0 |
| 0001 | 100 |
| 0010 | 101 |
| 0011 | 11100 |
| 0100 | 1100 |
| 0101 | 11101 |
| 0110 | 111100 |
| 0111 | 11111100 |
| 1000 | 1101 |
| 1001 | 111101 |
| 1010 | 1111100 |
| 1011 | 11111101 |
| 1100 | 1111101 |
| 1101 | 1111110 |
| 1110 | 111111110 |
| 1111 | 111111111 |

VLC2, N = 4

According to the present invention, the optimal VLC at each value of p(0) is the VLC that yields the fewest bits per symbol, i.e. the infimum of the curves shown in FIG. 1. This can be expressed in a mapping table (Table 2), or approximated by the function:

TABLE 2
$K = \{ \begin{matrix}0 , p ( 0 ) < 2 p ( 1 ) \\ 2 , p ( 0 ) \geq 7 p ( 1 ) \\ 1 , otherwise\end{matrix}$

| p(0) | VLC, K |
|---|---|
| 0.50 | 0 |
| 0.55 | 0 |
| 0.60 | 0 |
| 0.65 | 0 |
| 0.70 | 1 |
| 0.75 | 1 |
| 0.80 | 1 |
| 0.85 | 2 |
| 0.90 | 2 |
| 0.95 | 2 |
| 1.00 | 2 |

It should be noted that, although the above example uses three VLCs to illustrate the concept of the present invention, the procedure can be repeated using a different number of VLCs, using VLCs with other values of N, or to VLCs with different codewords to those used in Tables 1(a)-1(c).

In one embodiment, the present invention is applied to the decoding of fine-grained scalability information in H.264/AVC. According to H.264/AVC, fine-grained scalability information is decoded in two passes. First, a “significance pass” considers all those coefficients that were not coded in the base layer or in previous enhancement layers. Second, a “refinement pass” improves the precision of the remaining coefficients, i.e. those coefficients that were coded in a previous layer. In this embodiment, the probability of a refinement bit being one is p(1), and the probability of the refinement bit being zero is p(0).

The plot of FIG. 1 assumes that the symbols being decoded are independent of each other. In other words, the probability distribution of the next symbol cannot be conditioned upon the value of the current symbol. This assumption of independence is essentially true for refinement bits in FGS coding. By contrast, conventional systems for variable length coding aim to exploit correlation between symbols, and are therefore of limited use when coding independent values.

Although independent of each other, refinement bits can exhibit a skewed probability distribution., i.e. the values of p(0) and p(1) are often not equal. In this embodiment, the values of p(1) and p(0) are determined by observing previously-decoded refinement bits. The values could also be explicitly coded into the bit stream.

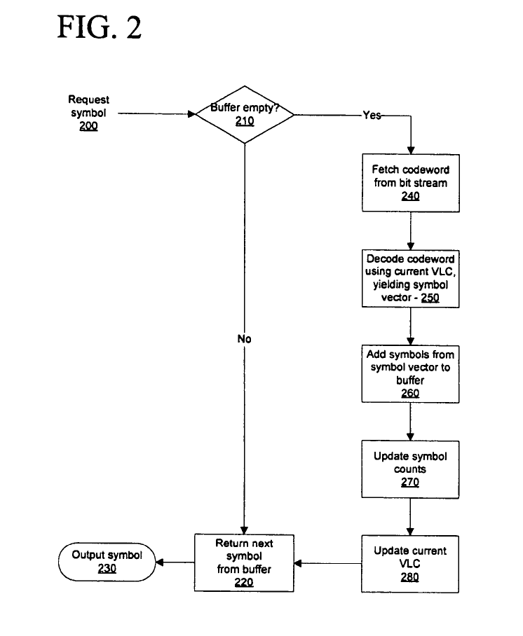

Having determined the appropriate VLC by, for example, employing Table 2, the regular VLC encoding/decoding process can be followed. A diagram of the decoding process is shown in FIG. 2. At step 200 in FIG. 2, a symbol is requested. At step 210, it is determined whether the buffer is empty. If the buffer is not empty, then the next symbol to be used is returned from the buffer at 220, and the symbol is output at step 230. If the buffer is empty, then a codeword is fetched from the bit stream at step 240. At step 250, the codeword is decoded using the current VLC. This yields a symbol vector. At step 260, symbols from the symbol vector are added to the buffer. At step 270, the symbol counts are updated. At step 280, the current VLC is updated, and the system then proceeds to steps 220 and 230 as discussed above.

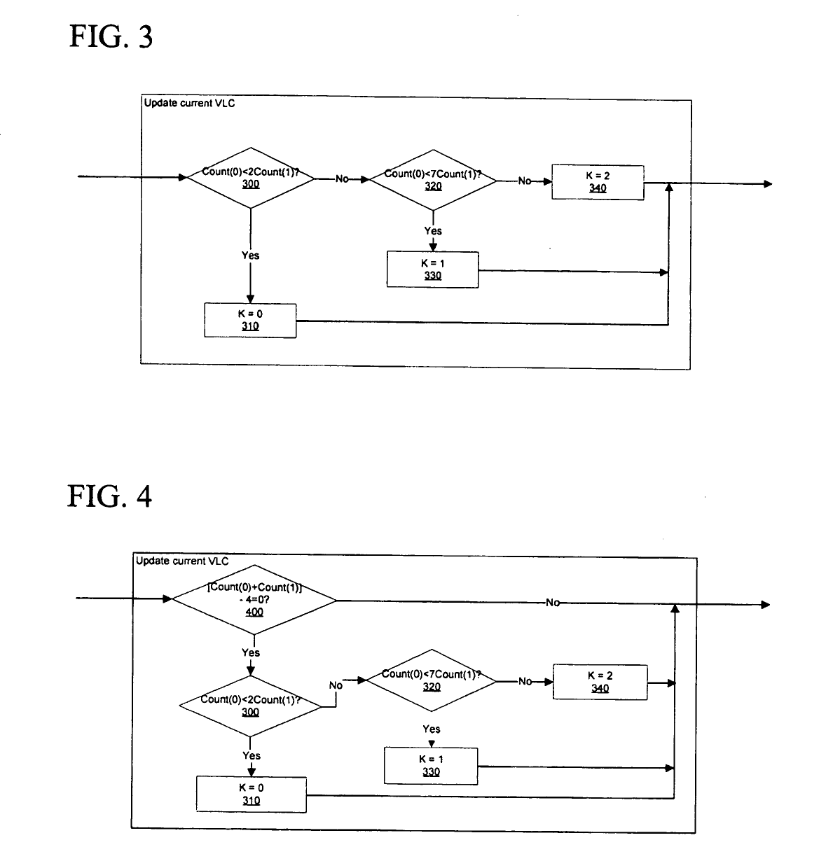

FIG. 3 is a flow chart showing a process for updating the current VLC for the process depicted in FIG. 2. At step 300, it is determined whether count(0)<2count(1). If count(0)<2count(1), then K is set to 0 at step 310. If count(0) is not less than 2count(1), it is determined whether count(0)<7count(1) at step 320. If count(0)<7count(1), then K is set to 1 at step 330. If count(0) is not less than 7count(1), then K is set to 2 at step 340.

The following is a discussion of several details that are involved in the implementation of various embodiments of the present invention for use in a practical source compression system. For the coder to self-adapt, the VLC selection must be “updated.” In other words, the value of K must be re-computed using either the table or the formula method described above. To achieve an optimal coding efficiency, this “update” should occur after each codeword is decoded, as shown in FIG. 2. However, in some cases (e.g., to reduce complexity) it may be desirable to reduce the frequency of such updates so that, for example, an update is performed after decoding every second or every third codeword. This “update frequency” may be designed in advance, may be explicitly indicated in the bit stream, or may be inferred based on coding history. For example, the “update frequency” may be changed dynamically based upon how often the selected VLC is observed to change.

The case where an update is performed for every fourth symbol is shown in FIG. 4. At step 400, it is determined whether [count(0)+count(1)]% 4=0, with “%” being the modulus operator. If not, then no update occurs. If the value does equal zero, then the steps that occur are substantially identical to those depicted in FIG. 3.

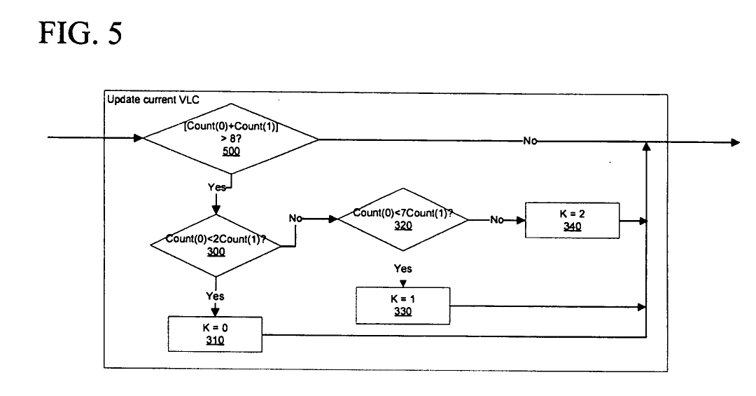

Initially, the probability measurements will be based on a limited number of observations. This increases the likelihood of a sub-optimal VLC being selected. To help overcome this issue, an “initial value” specifying the VLC can be used until the number of symbols observed reaches a certain limit. After the limit is reached, the normal update procedure described above is followed. The “initial value” specifying the VLC may either be designed in advance or indicated in the bit stream. This is illustrated in FIG. 5. At step 500 in FIG. 5, it is first determined whether [count(0)+count(1)] is greater than 8, which has been set as the threshold number of symbols. If this threshold has not been exceed, then no update occurs. If the threshold has been exceeded, then the process proceeds in a manner substantially identical to that depicted in FIG. 3. The process depicted in FIG. 4 can also be implemented in this situation.

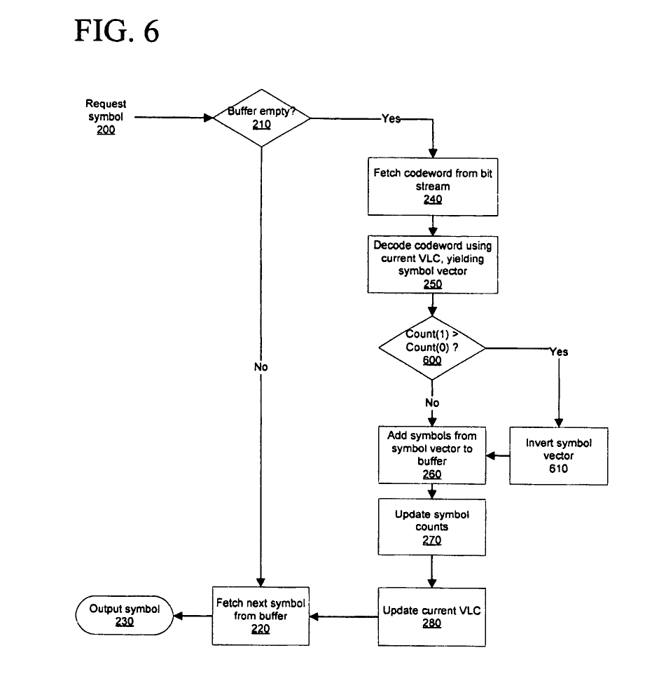

It should be noted that the probability of p(0) in FIG. 1 commences at p(0)=0.5. In other words, it depicts the case where p(0)≧p(1). Because symbol probabilities are measured at the decoder, the decoder is aware whether or not this is the case and “bit flips” the symbol vectors after decoding them if p(0)<p(1). Therefore, the plot of FIG. 1 can be considered to be symmetric about p(0)=0.5. This is represented in FIG. 6. The process of FIG. 6 is substantially identical to FIG. 2 but, after step 250, it is determined whether count(1)>count(0). If so, then the symbol vector is inverted at step 600 before proceeding to step 260.

Because the number of symbols in a symbol vector v̅ may be greater than one, individual symbols must be buffered until the buffer holds N symbols, after which the VLC codeword for v̅ may be encoded. If one or more symbols remain in the buffer when all symbols have been passed to the encoder, the buffer must be flushed to the bit stream. This involves selecting a VLC with a value of N that is less than or equal to the number of symbols remaining in the buffer, and then coding the buffer contents using that VLC. If necessary, the process is repeated until the buffer is empty.

To determine the VLC used in flushing the buffer in the binary case, one begins with FIG. 1 and excludes all curves for which N is greater than or equal to the value of N for the current VLC. For example, if the current VLC is VLC2, then VLC2 would be excluded, leaving VLC0 and VLC1. The value of p(0) is then compared to the infimum of the remaining curves to determine the optimal VLC for flushing the buffer. The decoder will be able to process the bit stream, provided it knows whether to decode a “full” codeword using the normal VLC or whether to process a buffer flush using a different VLC.

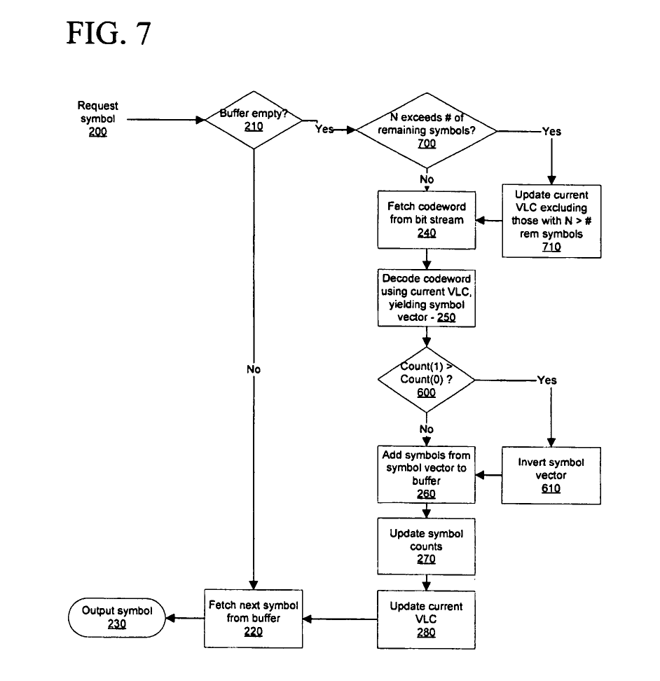

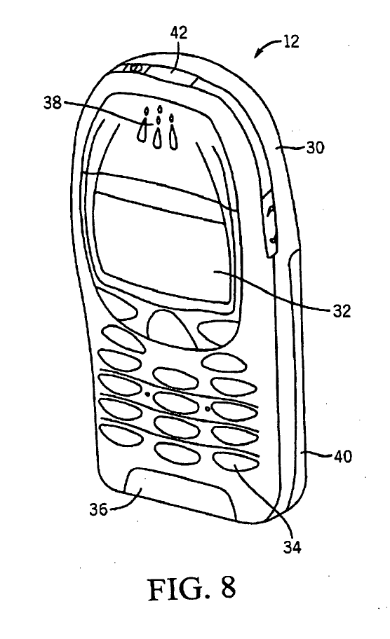

The decoder can determine which of the two cases applies by comparing the number of symbols remaining to be processed to the value of N for the current VLC. If N is less than or equal to the number of symbols remaining, the “full” codeword is decoded. Otherwise, a buffer flush is decoded. This process is illustrated in FIG. 7. FIG. 7 is substantially identical to FIG. 6, except that, after step 210, it is determined whether N exceeds the number of remaining symbols at step 700. If N exceeds this number, then, before proceeding to step 240, the current VLC is updated at step 710 to exclude those VLC's where N is greater than the number of remaining symbols.

Utilizing the number of symbols remaining to be decoded is another important characteristic of the present invention that distinguishes it from many other variable length coding methods. This number may either be explicitly decoded from the bit stream, it may be a design-time constant, or it may be inferred from other information in the bit stream.

In one embodiment, where the invention is used to decode FGS information from a bit stream containing video data, the flushing process may occur so that information is periodically aligned. For example, the flushing process may occur at the end of each 4×4 block or each macroblock. In another embodiment, again involving the decoding of FGS information from a bit stream containing video data, the flushing process may occur each time the type of syntax element changes. For example, all refinement bits may be coded, followed by a flush, followed by sign information, followed by another flush.

In yet another embodiment, again involving the decoding of FGS information from a bit stream containing video data, the decoder state is reset periodically, for example, once per slice or once per frame of video data.

In still another embodiment, the period of flushing is equal to the reset interval of the coder, effectively meaning that flushing does not occur. For example, various syntax elements are interleaved without flushing, or information from multiple blocks is coded without flushing.

As a result of the flushing process, a sub-optimal VLC may be used a fraction of the time. Generally, the loss in coding efficiency is small. This, coupled with the fact that the buffer size N is also small, means that the buffer can be flushed quite often compared to arithmetic coding. For example, in video coding, the buffer may be flushed every block (possibly less than 16 symbols). This results in much of the coding efficiency benefit associated with arithmetic coding but, due to more frequent buffer flushing, truncation of the bit stream may be more precisely controlled.

In an additional embodiment of the present invention, the number of symbols N in a vector v̅ may be allowed to vary rather than remaining constant. For example, by assigning another codeword to a longer run of zeros (or ones), coding efficiency at very high values of p(0) may be improved without over-filling the codeword table.

The basic design of the present invention may be applied to non-binary symbol alphabets, i.e. more than two symbols in the alphabet. For example, in the ternary case, the two-dimensional plot would become a three-dimensional surface. However, it should be noted that the function for selecting the optimal VLC becomes more complex as the alphabet size grows.

In another embodiment, the present invention is applied to the decoding of coded block patterns. The coded block pattern specifies spatial regions within a macroblock that contain values to be decoded. For example, in H.264/AVC, the CBP specifies which 8×8 blocks within a 16×16 macroblock contain values to be decoded.

According to the present invention, the probability of a block containing values to be decoded is p(1), and the probability of the block containing no values to be decoded is p(0). In this embodiment, the values of p(1) and p(0) are determined by observing previously-decoded CBP values. The values could also be explicitly coded into the bit stream.

In this embodiment of the present invention, codewords are decoded from the bit stream until enough binary values have been read to form a complete CBP. For example, in the case of a 16×16 macroblock and 8×8 blocks, there are four bits in a CBP. Therefore, if the possible VLCs are drawn from Table 1(a) and Table 1(b) and VLC0 is selected, four codewords would need to be read. If VLC1 is selected, only one codeword needs to be read.

In a further embodiment, the present invention is applied to the decoding of a coded block pattern where the CBP of a corresponding base layer macroblock is used in the decoding process. The CBP of the enhancement layer macroblock is partitioned into two parts. The first part (CBP0) contains the enhancement layer CBP bits for blocks for which the corresponding bit in the base layer CBP was zero. The second part (CBP1) contains the remaining enhancement layer CBP bits, i.e., when the corresponding bit in the base layer CBP was one. For example, if the base layer CBP is 0001 and the enhancement layer CBP is 1101, then CBP0 would contain the first three bits of the enhancement layer CBP, i.e. CBP0=110, and CBP1 would contain the remaining bits, i.e. CBP1=1.

The probabilities p(0) and p(1) are maintained separately for CBP0 (denoted by p₀(0) and p₀(1)) and for CBP1 (denoted by p₁(0) and p₁(1)). The optimal VLC is determined separately for each of CBP0 and CBP1, and the decoding of CBP0 and CBP1 proceeds independently.

In another embodiment of the present invention, the decision whether to split the CBP into CBP0 and CBP1 is made dynamically. For example, a cost function may be used to estimate the number of bits required to decode each of CBP0, CBP1, and the non-segmented CBP. One input to the cost function involves the values of pₖ(0). If the sum of the estimated number of bits to represent CBP0 and the estimated number of bits to represent CBP1 is less than the estimated number of bits required to decode the non-segmented CBP, the values of CBP0 and CBP1 are decoded independently. Otherwise, the non-segmented CBP is decoded.

In another embodiment, the present invention is applied to the decoding of Coded block flags (CBFs). CBFs indicate whether a region within a macroblock contains values to be decoded or not. In the existing FGS for H.264/AVC, CBFs are decoded independently. However, a coding efficiency gain can be realized by decoding multiple CBFs simultaneously, as for CBPs. The probability of previous CBFs being zero or one is measured, and this information is used to select a VLC for decoding. This is accomplished in the same manner as is the case for CBPs. Bit flipping is also used.

In one embodiment, when coding a vector of CBF values, the CBFs from corresponding blocks in the base layer are utilized in determining the VLC to be used. In another embodiment, the CBF values from corresponding blocks in the base layer are utilized in segmenting the enhancement layer CBF. For example, in a similar manner to the CBP, values CBF0 and CBF1 might be formed, with CBF0 containing enhancement layer CBF values for which the base layer CBF was zero, and CBF1 containing enhancement layer CBF values for which the base layer CBF was one. These segmented CBF values may be coded individually, for example, using a method substantially identical to the method for coding a segmented CBP.

In another embodiment, the present invention is applied to the decoding of FGS information in H.264/AVC, and more specifically to the decoding of end of block (EOB) markers in the significance pass. Presently, H.264/AVC uses a single EOB symbol to indicate whether there are non-zero values remaining in the block. The present invention involves the use of multiple EOB symbols, with some or all of the EOB symbols used indicating information about the magnitude of coefficients from that block that were designated as “significant” during the significance pass. This information may include the number of coefficients in the block with a magnitude greater than one. Alternatively, the information may include the maximum magnitude of coefficients decoded in the significance pass. The information could also include a combination of both of these items.

The number of coefficients in the block with a magnitude greater than one (x) and the maximum magnitude of coefficients decoded in the significance pass (y) may be combined using a separable linear function, such as EOBoffset=16y+x. In this situation, in the decoding process, y=EOBoffset/16 and x=EOBoffset% 16, i.e., x is the remainder when EOBoffset is divided by 16. In some cases, a combination of linear functions may be used. For example, EOBoffset=2x+y% 2, if y<4 and EOBoffset=16y+x otherwise.

The number of decoded coefficients (z) may also be incorporated into the linear equation. For example, in one embodiment, EOBoffset 2(x−1)+y% 2, if y<4 and EOBoffset=z(y−2)+x−1, otherwise. Therefore, in the decoding process, x=(EOBoffset/2)+1, y=(EOBoffset% 2)+2, if EOBoffset<2z and x=(EOBoffset% z)+1, y=(EOBoffset/z)+2, otherwise.

The present invention therefore covers the particular case where (1) one EOB symbol is used to indicate an end of a block where no coefficient decoded in the significance pass has a magnitude greater than one; and (2) the remaining EOB symbols indicate not only an end of block condition, but additionally indicate the number of coefficients with magnitude greater than one and the maximum magnitude.

In one embodiment of the invention, the actual symbols used as EOB markers that include magnitude information are arbitrary but known to the decoder. For example, these markers can be fixed during codec design or explicitly indicated in the bit stream. In this case, the decoded symbol is located in a mapping table. The index of the symbol provides the value of EOBoffset to be used in the above equations. For example, if the symbol “9” is decoded, then, according to the example in Table 3 below, EOBoffset=1. Through the use of the linear equations above, the values of x and y may then be determined.

TABLE 3

| EOBoffset | EOB symbol |
|---|---|
| 0 | 6 |
| 1 | 9 |
| 2 | 3 |
| 3 | 1 |
| 4 | 15 |
| 5 | 12 |
| 6 | 7 |
| 7 | 10 |

In one particular embodiment of the invention, the EOB symbols that incorporate magnitude information are sequential. In this case, after decoding a symbol, the first EOB symbol is subtracted form the decoded symbol to give EOBoffset. An example of EOB sequential values is depicted in Table 4. In this case, if the EOB symbol “9” is decoded, then the value “6” is subtracted to give EOBoffset=3.

TABLE 4

| EOBoffset | EOB symbol |
|---|---|
| 0 | 6 |
| 1 | 7 |
| 2 | 8 |
| 3 | 9 |
| 4 | 10 |
| 5 | 11 |
| 6 | 12 |
| 7 | 13 |

In another embodiment of the invention, the EOB symbols containing magnitude information are not only sequential, but start from the first “illegal” run length. For example, if a block contains 16 coefficients, but 10 coefficients have been already processed, then the maximum “run” of zeros before the next non-zero value is 5. It is not possible for a “run” of length 6 or greater to occur, so symbols 6 and greater are considered “illegal”. In this situation, the EOB symbols containing magnitude information would be numbered sequentially starting at 6. In this embodiment, the symbol used for a given EOBoffset may vary from one block to another.

In another embodiment of the present invention, the symbol indicating an EOB and no magnitudes greater than one may be bounded by the first illegal symbol. For example, if the symbol “5” is assigned to indicate an EOB where no magnitudes are greater than one, and two coefficients remain to be coded in a block (so that “3” is the first illegal symbol), then the symbol “3” would be used rather than “5” to indicate an EOB with no coefficients of magnitude greater than one.

In still another embodiment of the present invention, the first EOB symbol indicating magnitudes greater than one is shifted by one depending upon whether the number of coefficients remaining to be coded exceeds the symbol signifying an EOB with no coefficients of magnitude greater than one. For example, if the symbol “5” is assigned to mean an EOB where no magnitudes are greater than one, and less than five coefficients remain to be coded, then the values in the “EOB symbol” column of Table 4 would be incremented by one.

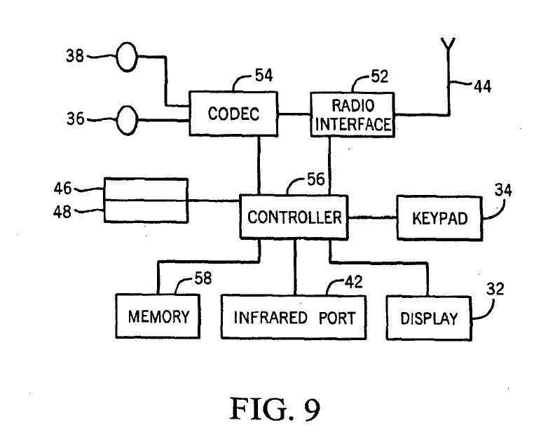

FIGS. 8 and 9 show one representative mobile telephone 12 within which the present invention may be implemented. It should be understood, however, that the present invention is not intended to be limited to one particular type of mobile telephone 12 or other electronic device. Instead, the present invention can be incorporated into virtually any type of electronic device, including but not limited to laptop and desktop computers, personal digital assistants, integrated messaging devices, printers, scanners, fax machines and other devices.

The mobile telephone 12 of FIGS. 8 and 9 includes a housing 30, a display 32 in the form of a liquid crystal display, a keypad 34, a microphone 36, an ear-piece 38, a battery 40, an infrared port 42, an antenna 44, a smart card 46 in the form of a UICC according to one embodiment of the invention, a card reader 48, radio interface circuitry 52, codec circuitry 54, a controller 56 and a memory 58. Individual circuits and elements are all of a type well known in the art, for example in the Nokia range of mobile telephones.

The present invention is described in the general context of method steps, which may be implemented in one embodiment by a program product including computer-executable instructions, such as program code, executed by computers in networked environments.

Generally, program modules include routines, programs, objects, components, data structures, etc. that perform particular tasks or implement particular abstract data types. Computer-executable instructions, associated data structures, and program modules represent examples of program code for executing steps of the methods disclosed herein. The particular sequence of such executable instructions or associated data structures represents examples of corresponding acts for implementing the functions described in such steps.

Software and web implementations of the present invention could be accomplished with standard programming techniques with rule-based logic and other logic to accomplish the various database searching steps, correlation steps, comparison steps and decision steps. It should also be noted that the words “component” and “module” as used herein, and in the claims, is intended to encompass implementations using one or more lines of software code, and/or hardware implementations, and/or equipment for receiving manual inputs.

The foregoing description of embodiments of the present invention have been presented for purposes of illustration and description. It is not intended to be exhaustive or to limit the present invention to the precise form disclosed, and modifications and variations are possible in light of the above teachings or may be acquired from practice of the present invention. The embodiments were chosen and described in order to explain the principles of the present invention and its practical application to enable one skilled in the art to utilize the present invention in various embodiments and with various modifications as are suited to the particular use contemplated.

What is claimed is:

1. A method for decoding compressed data from a bit stream, the method comprising:
fetching a codeword representing a symbol vector including at least one symbol from the bit stream;
decoding the codeword using a variable length code, the decoding of the codeword yielding the symbol vector including at least one symbol;
adding the at least one symbol from the symbol vector to a buffer;
updating the variable length code based at least in part upon the probability distribution of symbols previously decoded; and
returning the next symbol from the buffer.

2. The method of claim 1, further comprising:
before updating the variable length code, updating symbol counters to reflect the symbols that were added to the buffer; and
utilizing the symbol counters in determining the probability distribution of symbols that were previously decoded.

3. The method of claim 1, further comprising:
before fetching the codeword from the bit stream, determining whether the buffer is empty;
if the buffer is empty, proceeding to fetch the codeword; and
if the buffer is not empty, immediately returning the next symbol from the buffer and not decoding the codeword, adding symbols, or updating the current variable length code.

4. The method of claim 1, further comprising:
after decoding the codeword, determining whether the probability of the requested symbol having a first value is greater than the probability of the symbol having a second particular value; and
if the probability of the symbol having a first value is greater than the probability of the symbol having a second value, inverting the symbol vector.

5. The method of claim 1, further comprising:
before fetching the codeword from the bit stream, determining the number of symbols in symbol vectors corresponding the variable length code;
determining whether the number of symbols is greater than the number of symbols remaining to be processed; and
if the number of symbols is greater than the number of symbols remaining to be processed, providing a new variable length code for which the number of symbols in a symbol vector is not greater than the number of symbols remaining to be processed.

6. The method of claim 1, wherein the updated variable length code is selected so as to possess the fewest bits per symbol from the available variable length codes for the probability distribution of symbols previously decoded.

7. The method of claim 1, wherein the variable length code is only updated periodically.

8. The method of claim 7, wherein the period is determined based at least in part upon the variable length code selected in one or more previous updates of the variable length code.

9. The method of claim 1, wherein the updating of the variable length code is triggered by an explicit signal in the bit stream or by inferred characteristics of the source data.

10. The method of claim 1, wherein the variable length code is not updated until the number of symbols decoded reaches a predetermined threshold.

11. The method of claim 2, wherein the symbol counters are scaled by a scaling factor either periodically or when one or more symbol counters reach a predetermined threshold.

12. A computer program product for decoding compressed data from a bit stream, comprising:
computer code for fetching a codeword representing a symbol vector including at least one symbol from the bit stream;
computer code for decoding the codeword using a variable length code, the decoding of the codeword yielding the symbol vector including at least one symbol;
computer code for adding the at least one symbol from the symbol vector to a buffer;
computer code for updating the variable length code based at least in part upon the probability distribution of symbols previously decoded; and
computer code for returning the next symbol from the buffer.

13. The computer program product of claim 12, further comprising:
computer code for before updating the variable length code, updating symbol counters to reflect the symbols that were added to the buffer; and
computer code for utilizing the symbol counters in determining the probability distribution of symbols that were previously decoded.

14. The computer program product of claim 12, further comprising:
computer code for before fetching the codeword from the bit stream, determining whether the buffer is empty;
computer code for, if the buffer is empty, proceeding to fetch the codeword; and
computer code for, if the buffer is not empty, immediately returning the next symbol from the buffer and not decoding the codeword, adding symbols, or updating the current variable length code.

15. The computer program product of claim 12, further comprising:
computer code for, after decoding the codeword, determining whether the probability of the requested symbol having a first value is greater than the probability of the symbol having a second particular value; and
computer code for, if the probability of the symbol having a first value is greater than the probability of the symbol having a second value, inverting the symbol vector.

16. The computer program product of claim 12, further comprising:
computer code for, before fetching the codeword from the bit stream, determining the number of symbols in symbol vectors corresponding the variable length code;
computer code for determining whether the number of symbols is greater than the number of symbols remaining to be processed; and
computer code for, if the number of symbols is greater than the number of symbols remaining to be processed, providing a new variable length code for which the number of symbols in a symbol vector is not greater than the number of symbols remaining to be processed.

17. The computer program product of claim 12, wherein the updated variable length code is selected so as to possess the fewest bits per symbol from the available variable length codes for the probability distribution of symbols previously decoded.

18. The computer program product of claim 12, wherein the variable length code is updated periodically.

19. The computer program product of claim 18, wherein the period is determined based at least in part upon the variable length code selected in one or more previous updates of the variable length code.

20. The computer program product of claim 12, wherein the variable length code is not updated until the number of symbols decoded reaches a predetermined threshold.

21. The computer program product of claim 12, wherein the symbol counters are scaled by a scaling factor either periodically or when one or more symbol counters reach a predetermined threshold.

22. An electronic device, comprising:
a processor; and
a memory unit operatively connected to processor and including a computer program product for decoding compressed data from a bit stream, comprising:
computer code for fetching a codeword representing a symbol vector including at least one symbol from the bit stream,
computer code for decoding the codeword using a variable length code, the decoding of the codeword yielding the symbol vector including at least one symbol,
computer code for adding the at least one symbol from the symbol vector to a buffer,
computer code for updating the variable length code based at least in part upon the probability distribution of symbols previously decoded, and
computer code for returning the next symbol from the buffer.

23. The electronic device of claim 22, wherein the computer program product further comprises:
computer code for before updating the variable length code, updating symbol counters to reflect the symbols that were added to the buffer; and
computer code for utilizing the symbol counters in determining the probability distribution of symbols that were previously decoded.

24. The electronic device of claim 22, wherein the computer program product further comprises:
computer code for before fetching the codeword from the bit stream, determining whether the buffer is empty;
computer code for, if the buffer is empty, proceeding to fetch the codeword; and
computer code for, if the buffer is not empty, immediately returning the next symbol from the buffer and not decoding the codeword, adding symbols, or updating the current variable length code.

25. The electronic device of claim 22, wherein the computer program product further comprises:
computer code for, after decoding the codeword, determining whether the probability of the requested symbol having a first value is greater than the probability of the symbol having a second particular value; and
computer code for, if the probability of the symbol having a first value is greater than the probability of the symbol having a second value, inverting the symbol vector.

26. The electronic device of claim 22, wherein the computer program product further comprises:
computer code for, before fetching the codeword from the bit stream, determining the number of symbols in symbol vectors corresponding the variable length code;
computer code for determining whether the number of symbols is greater than the number of symbols remaining to be processed; and
computer code for, if the number of symbols is greater than the number of symbols remaining to be processed, providing a new variable length code for which the number of symbols in a symbol vector is not greater than the number of symbols remaining to be processed.

27. The electronic device of claim 22, wherein the updated variable length code is selected so as to possess the fewest bits per symbol from the available variable length codes for the probability distribution of symbols previously decoded.

28. The electronic device of claim 22, wherein the variable length code is updated periodically.

29. The electronic device of claim 28, wherein the period is determined based at least in part upon the variable length code selected in one or more previous updates of the variable length code.

30. The electronic device of claim 22, wherein the variable length code is not updated until the number of symbols decoded reaches a predetermined threshold.

31. The electronic device of claim 22, wherein the symbol counters are scaled by a scaling factor either periodically or when one or more symbol counters reach a predetermined threshold.

32. A method of encoding data for transmission in a bit stream, comprising:
examining a plurality of symbols to be encoded; and
selecting a codeword to represent at least one of the plurality of symbols, the codeword being selected based at least upon the number of instances in which each of the plurality of symbols have been previously encoded.

33. The method of claim 32, wherein the length of the codeword is based at least in part upon the number of instances in which each of the plurality of symbols have been previously encoded.

34. A method of encoding data to a bit stream, the method comprising:
adding a symbol to a buffer;
determining whether the number of symbols in the buffer equals the number of symbols in a symbol vector for a variable length code;
if the number of symbols in the buffer equals the number of symbols in the symbol vector:
forming the symbol vector from the symbols in the buffer;
encoding the symbol vector using the variable length code;
flushing the buffer; and
updating the variable length code based at least in part upon the probability distribution of symbols previously encoded.

35. The method of claim 34, further comprising:
before updating the variable length code, updating symbol counters to reflect the symbols that were added to the buffer; and
utilizing the symbol counters in determining the probability distribution of symbols that were previously encoded.

36. The method of claim 34, further comprising:
before encoding the symbol vector using the variable length code, determining whether the probability of a symbol having a first value is greater than the probability of the symbol having a second value; and
if the probability of the symbol having a first value is greater than the probability of the symbol having a second value, inverting the symbol vector.

37. The method of claim 34, further comprising:
before determining whether the number of symbols in the buffer equals the number of symbols in a symbol vector for a variable length code, determining whether any further symbols remain to be encoded; and
if no further symbols remain to be encoded, providing a new variable length code for which the number of symbols in a symbol vector is not greater than the number of symbols in the buffer.

38. The method of claim 34, wherein the updated variable length code is selected so as to possess the fewest bits per symbol from the available variable length codes for the probability distribution of symbols previously encoded.

39. The method of claim 34, wherein the variable length code is only updated periodically.

40. The method of claim 39, wherein the period is determined based at least in part upon the variable length code selected in one or more previous updates of the variable length code.

41. The method of claim 34, wherein the updating of the variable length code is triggered by an explicit signal in the bit stream or by inferred characteristics of the source data.

42. The method of claim 40, wherein the variable length code is not updated until the number of symbols encoded reaches a predetermined threshold.

43. The method of claim 35, wherein the symbol counters are scaled by a scaling factor either periodically or when one or more symbol counters reach a predetermined threshold.
